(19) United States
(12) Patent Application Publication
(10) Pub. No.: US 2013/0114212 A1
(43) Pub. Date: May 9, 2013

(54) ELECTRICALLY CONDUCTIVE MATERIAL AND ELECTRONIC DEVICE USING SAME

(71) Applicant: DENSO CORPORATION, Kariya-city (JP)

(72) Inventors: Kazuo Tada, Kariya-city (JP); Kouji Kondoh, Toyohashi-city (JP); Kouhei Fujihara, Kariya-city (JP); Yoshihiko Shiraishi, Nagoya-city (JP)

(73) Assignee: DENSO CORPORATION, Kariya-city (JP)

(21) Appl. No.: 13/668,748

(22) Filed: Nov. 5, 2012

(30) Foreign Application Priority Data
Nov. 7, 2011 (JP) 2011-243231
Jul. 27, 2012 (JP) 2012-167062

(51) Int. Cl. H01B 1/02; H05K 7/20

(52) U.S. Cl. CPC H01B 1/026; H05K 7/20409; H01B 1/02
USPC 361/712; 252/512; 252/514

(57) ABSTRACT

An electrically conductive material used in the formation of heat-releasing filled via holes in an electronic component-incorporated multilayer circuit board with a heat radiation member, in which the electrically conductive material comprises metal particles as a conductive metal which is a mixture of a first conductive metal consisting of silver (Ag) or copper (Cu) and a second conductive metal consisting of tin (Sn), and a ratio of the atomicity of tin to the atomicity of silver or copper and tin is 27 to 40%, and an electronic device using the same.

### CROSS-REFERENCE TO RELATED APPLICATION

This application is based on Japanese Patent Application No. 2011-243231 filed on Nov. 7, 2011, and Japanese Patent Application No. 2012-167062 filed on Jul. 27, 2012, the disclosures of which are incorporated herein by reference in their entirety.

### BACKGROUND OF THE INVENTION

1. Field of the Invention

The present invention relates to an electrically conductive material used in the formation of heat-releasing filled via holes in an electronic component-incorporated multilayer circuit board with a heat radiation member, and an electronic device, typically a semiconductor device, comprising an electronic component-incorporated multilayer circuit board with heat-releasing filled via holes, formed from the electrically conductive material, and a heat radiation member.

2. Description of the Related Art

Hitherto, a wide variety of semiconductor devices which comprise a multilayer circuit board having incorporated therein a semiconductor chip in which the semiconductor chip is electrically connected through, for example, filled through holes formed from an electrically conductive material to a conductor pattern, i.e., a pattern of conductive materials such as copper. For example, Japanese Unexamined Patent Publication (Kokai) No. 2010-73581 describes a semiconductor device comprising a multilayer circuit board which comprises a plurality of laminated resin layers, and has a semiconductor chip disposed therein. The multilayer circuit board described in this Japanese patent publication is a “PALAP” (Patterned Prepreg Lay Up Process) board produced by laminating the plurality of resin layers, made of, for example, liquid crystal polymer, to obtain a precursor of the multilayer circuit board, followed by pressing, at once, the precursor, i.e., resulting in a laminated body of the resin layers, under application of heat and pressure.

In this prior art semiconductor device, a heat radiation member such as a heat sink is laminated to the multilayer circuit board and is thermally connected to the semiconductor chip to ensure release of heat, generated in the semiconductor chip, through the heat radiation member. In this device, the thermal connection of the semiconductor chip with the heat radiation member is carried out through a heat-releasing via formed in a thickness direction in the resin layers constituting the circuit board. The heat-releasing via is formed by filling a via with a material having a good thermal conductivity, and has a flat configuration similar to that of the semiconductor chip. Generally, the heat-releasing via is formed by hardening the filled conductive material, typically metal paste.

Generally, the semiconductor chip is flat or tablet shaped, and thus has one surface having an electrode pad which is also referred to as an upper surface or a circuit surface, and another surface opposed to the electrode pad which is also referred to as a lower surface or a back surface.

The heat radiation member is generally applied to a back surface of the multilayer circuit board so as to be positioned in a side of the back surface of the semiconductor chip. The heat-releasing via is formed in a resin layer between a back surface of the semiconductor chip and the heat radiation member.

### SUMMARY OF THE INVENTION

In the prior art semiconductor devices which comprise a multilayer circuit board having incorporated therein a semiconductor chip and a heat-releasing filled via used to outwardly radiate heat of the semiconductor chip from the circuit board, when the filled via is formed from metal powder as the electrically conductive material, the metal being represented by the formula: X—Sn in which X is silver (Ag) or copper (Cu), there arise the following problems if a ratio of tin (Sn) to X, i.e., Ag or Cu, is out of the desired range.

First, when heating to a temperature of 150 to 200° C. under applied pressure, the metal powder X—Sn in the electrically conductive material can form a metal alloy represented by the formula: X₃Sn. However, the metal powder are not completely consumed during this alloy production step, and thus some of the unused Sn component may remain in the conductive material. Thus, the remaining Sn component can be diffusion-bonded with the semiconductor chip and the heat radiation member, when the temperature is increased to 220° C. or more.

Second, if an excess amount of the Sn component is contained in the conductive material due to incomplete consumption of the remaining Sn component in the diffusion bonding, the excess Sn component can be changed to a liquid state. At this stage, since the semiconductor chip is positioned in an opening or cavity, i.e., through hole, of the resin layer, the liquid-type Sn component may migrate through a small gap formed between a side surface of the semiconductor chip and the through hole of the resin layer as a function of the capillary phenomenon of the gap. Thus, the Sn component remained in the electrically conductive material can be introduced through a side surface of the semiconductor chip into the circuit surface of the semiconductor chip. Since the liquid-type Sn component can be in contact with the conductor pattern on the circuit surface, a short circuit may occur between the circuit surface and the back surface of the semiconductor chip.

In view of the above problems, it is an object of the present invention to prevent a short circuit between the circuit surface and the back surface of the semiconductor chip when the semiconductor device is produced by laminating a plurality of resin layers, followed by heating at once the resulting precursor of the multilayer circuit board under application of pressure.

It is another object of the present invention to provide an electrically conductive material which can be effectively used in the production of the semiconductor device which has heat-releasing filled vias in a semiconductor chip-incorporated multilayer circuit board with a heat radiation member, and is produced by laminating a plurality of resin layers, followed by heating at once the resulting precursor of the multilayer circuit board under application of pressure.

It is another object of the present invention to provide a semiconductor device comprising a semiconductor chip-incorporated multilayer circuit board with heat-releasing filled vias, formed from an electrically conductive material, and a heat radiation member, and having no prior art problem.

These and other objects of the present invention will be easily understood from the following descriptions of the preferred embodiments of the present invention.

The inventors of the present invention have conducted intensive studies for accomplishing the objects described above, and have discovered that the above objects can be accomplished if the electrically conductive material is constituted so that it comprises metal particles, i.e. particles of metal as a conductive metal, which is a mixture of a first conductive metal consisting of silver (Ag) or copper (Cu) and a second conductive metal consisting of tin (Sn), wherein a ratio of the atomicity of tin to the atomicity of silver or copper and tin is controlled to be within 27 to 40%.

Further, the inventors have discovered that the short circuit problem described above can be effectively prevented if a size of the heat-releasing filled vias is controlled with regard to a size of the semiconductor chip used in combination of the heat-releasing filled vias.

According to one aspect of the present invention, there is provided an electrically conductive material used in the formation of heat-releasing filled via holes in an electronic component-incorporated multilayer circuit board with a heat radiation member, in which the electrically conductive material comprises metal particles as a conductive metal which is a mixture of a first conductive metal consisting of silver (Ag) or copper (Cu) and a second conductive metal consisting of tin (Sn), and a ratio of the atomicity of tin to the atomicity of silver or copper and tin is 27 to 40%.

In the present invention, the electronic component includes a wide variety of electronic components conventionally used in the production of electronic devices such as capacitors and chips, typically semiconductor chips such as IC chips and transistor chips.

In the electrically conductive material according to the present invention, the electrically conductive material is preferably an electrically conductive paste, i.e., metal paste comprising the particles of conductor metal in an organic binder. Basically, the electrically conductive paste may be any conventional electrically conductive paste, except that the conductor metal has to be a mixture of Ag or Cu and Sn, and a ratio of the atomicity of Sn to the atomicity of Ag or Cu and Sn is in the range of 27 to 40%.

For Example, the electrically conductive paste may comprise an organic binder such as cellulose resin, for example, ethyl cellulose and nitrocellulose, a solvent such as diethylene glycol monobuthylether acetate, and an inorganic binder such as glass frit (powdered glass), in addition to the particles of the conductor metal described above.

In the present invention, the multilayer circuit board is not restricted to the specific circuit boards insofar as the circuit boards can satisfy the requirements of the present invention. Preferably, the multilayer circuit comprises two or more laminated conductive resin layers and at least one interlayer of the conductive resin having at least one cavity or opening (through hole) in which one or more electronic components are built-in, the interlayer being sandwiched between the adjacent resin layers,

the heat radiation member such as the heat sink is laminated to one or both surfaces of the multilayer circuit board, and

one or more heat-releasing filled via holes are formed in at least one of the laminated conductive resin layers, and the electronic components and the heat radiation member are thermally connected with each other via the filled via holes to radiate heat, generated in the electronic components, from the heat radiation member.

Preferably, in the multilayer circuit board of the present invention, the heat-releasing filled via holes have a heat-receiving surface which is in contact with a heat-releasing surface of the electronic components, and the heat-receiving surface of the filled via holes has a surface area which is smaller than that of the heat-releasing surface of the electronic components. If the heat-releasing filled via hole has such a constitution, it becomes possible to prevent the short circuit problem, mentioned above, during heating of the laminated resin layers each of which is made of an electrically conductive resin such as thermoplastic resin, under application of pressure.

Further, one or more heat-releasing filled via holes may be formed in the conductive resin layer. For example, when one via hole is contained in the resin layer, it is preferred that the via hole be in the form of a rectangular cross-section, as is conventionally carried out in the field of circuit boards. However, if desired, the rectangular through hole may be replaced with a combination of two or more through holes each of which is in the form of, for example, cylindrical rods, as is also conventionally carried out in the field of circuit boards.

According to another aspect of the present invention, there is provided an electronic device comprising an electronic component-incorporated multilayer circuit board with heat-releasing filled via holes, and a heat radiation member.

In the electronic device, the multilayer circuit board comprises two or more laminated conductive resin layers and at least one conductive resin interlayer having at least one cavity in which one or more electronic components are built-in, the interlayer being sandwiched between the adjacent resin layers,

the heat radiation member is laminated to one or both surfaces of the multilayer circuit board,

one or more heat-releasing filled via holes are formed in the laminated conductive resin layers, and the electronic components and the heat radiation member are thermally connected to each other to radiate heat, generated in the electronic components, from the heat radiation member, and

the heat-releasing filled via holes comprise, filled therein, a sintered product of an electrically conductive material comprising metal particles as a conductive metal which is a mixture of a first conductive metal consisting of Ag or Cu and a second conductive metal consisting of Sn, and a ratio of the atomicity of Sn to the atomicity of Ag or Cu and Sn is 27 to 40%.

The electronic devices according to the present invention can be advantageously widely used such as in including vehicles, electronic products, home products and others. Typically, the electronic device is preferably used in automotive parts.

In the practice of the present invention, the multilayer circuit boards and the electronic devices having incorporated therein the circuit board according to the present invention can be preferably produced with the shortened process with the reduced number of fabrication steps and with a high reliability using the “PALAP” (Patterned Prepreg Lay Up Process) board production process described in, for example, Japanese Unexamined Patent Publication (Kokai) No. 2011-249745.

### BRIEF DESCRIPTION OF THE DRAWINGS

FIG. 1 is a cross-sectional view schematically showing a typical example of the semiconductor device according to the preferred embodiment of the present invention;

FIG. 2 is a cross-sectional view of the semiconductor device of FIG. 1 showing works used in the production of the illustrated device;

FIG. 3 is a cross-sectional view schematically showing another example of the semiconductor device according to the preferred embodiment of the present invention;

FIG. 4 is a cross-sectional view showing one drawback of the prior art semiconductor device;

FIG. 5 is a cross-sectional view of the prior art semiconductor device of FIG. 6 showing works used in the production of the illustrated device;

FIG. 6 is a cross-sectional view showing another drawback of the prior art semiconductor device illustrated in FIG. 5;

FIG. 7 is a graph showing the test results of the electrically conductive material (Ag—Sn) used in the examples; and

FIG. 8 is a graph showing the test results of the electrically conductive material (Cu—Sn) used in the examples.

### DESCRIPTION OF THE PREFERRED EMBODIMENTS

The present invention will be further described with regard to the preferred embodiments of the present invention referring to the accompanying drawings.

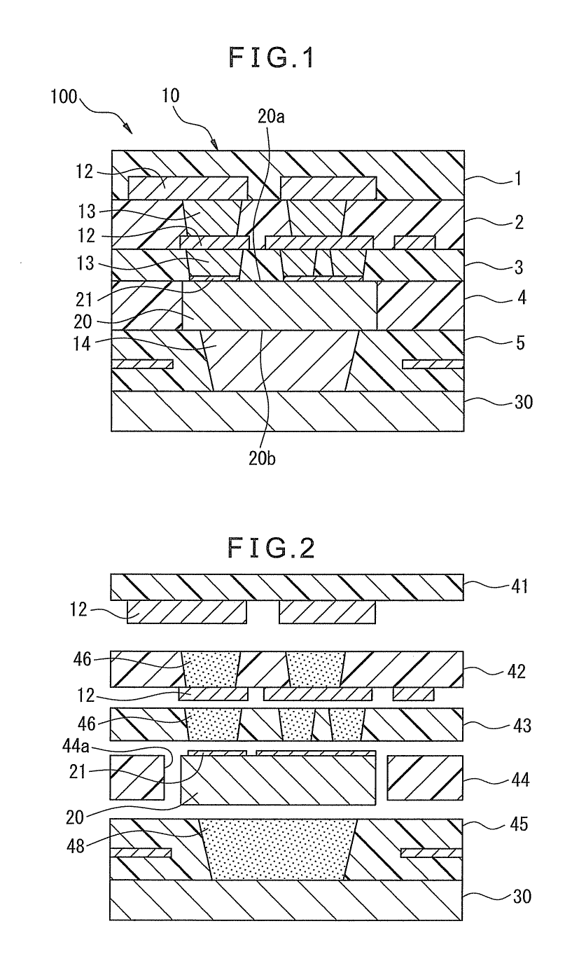

As is illustrated in FIGS. 1 and 2, the semiconductor device 100 comprises a multilayer board (circuit board) 10 comprising a plurality of laminated resin layers 1 to 5 made of a resin such as thermoplastic resin,

a plate-shaped semiconductor chip 20 disposed in a cavity 44a of the resin layer 44, and

a heat radiation member 30 laminated to the circuit board 10 in order to release heat of the semiconductor chip 20.

In the illustrated semiconductor device 100, the semiconductor device 20 has an upper surface 20a deposited thereon an electrode pad 21 and a lower surface 20b opposed to the heat radiation member 30.

Further, the circuit board 10 has a heat-releasing via hole 14 made of an electrically conductive material in an inner portion of the board 10. The heat-releasing via hole 14 is also referred to as a via or through hole, and is used to thermally connect another surface 20b of the semiconductor chip 20 with the heat radiation member 30. The electrically conductive material of the via hole contains a mixture of powders of Ag metal or Cu metal and powders of Sn. In the mixed powders of the metal Ag or Cu and the metal Sn, a ratio of the atomicity of Sn to the atomicity of Ag or Cu and Sn is in the range of 27 to 40%.

According to the present invention, since the ratio of the atomicity of Sn to the atomicity of Ag or Cu and Sn is not more than 40%, as is appreciated from the following descriptions and examples, it is possible in the semiconductor device 100 to prevent a migration of the Sn component of the conductive material constituting the via hole 14 into a side surface of the semiconductor chip 20, thereby preventing a short circuit problem between both surfaces of the semiconductor chip 20.

Further, since the ratio of the atomicity of Sn to the atomicity of Ag or Cu and Sn is not less than 27%, it becomes possible in the semiconductor device 100 to sufficiently carry out a diffusion bonding of the conductive material to the semiconductor chip 20 and the heat radiation member 30 without generating a remainder constituting the unused Sn component in the conductive material.

Referring again to FIG. 1, the illustrated semiconductor device 100 is an in-vehicle semiconductor device, and thus is mounted on, for example, an in-vehicle electronic product such as ECU of the engine.

The semiconductor device 100 comprises a multilayer circuit board 10, a semiconductor chip 20 such as silicon chip disposed within the circuit board 10, and a heat radiation member 30 thermally connected to the semiconductor chip 20.

The multilayer circuit board 10 is a laminated circuit board of five resin layers 1 to 5 produced by the “PALAP” process. The resin layers 1 to 5 are made of a film of the thermoplastic resin such as liquid crystal polymer, and after lamination thereof, the resin layers 1 to 5 are subjected to a thermal pressing process, including pressing the layers with heating, to produce an integrally bonded laminate.

Hereinafter, five resin layers 1 to 5 in FIG. 1 are described in the following order, i.e., the uppermost resin layer positioned in an upper surface of the board 10 is called as a first resin layer 1. The next resin layer positioned below the first resin layer 1 is referred to as a second resin layer 2. The next resin layer positioned below the second resin layer 2 is referred to as a third resin layer 3. Similarly, two layers positioned below the third resin, layer 3 are referred to as a fourth resin layer 4 and a fifth resin layer 5, respectively.

The semiconductor chip 20 includes a wide variety of chips such as IC chips made of, for example, silicon semiconductor, and transistor elements. In the illustrated embodiment, the semiconductor chip 20 is a plate-shaped chip having a rectangular cross-section, and has an electrode pad 21 on a surface 20a of the chip 20 as is illustrated in FIG. 1. The illustrated electrode pad 21 is formed from an aluminum (Al) metal.

Hereinafter, a surface 20a of the chip 20 having the electrode pad 21 is referred to as a circuit surface or an upper surface, and another surface 20b of the chip 20 opposed to the upper circuit surface 20a bearing the electrode pad 21 is referred to as a back surface.

The semiconductor chip 20 is embedded within the multilayer circuit board 10. In the illustrated embodiment, the semiconductor chip 20 is disposed in the fourth resin layer 4 as an interlayer. Further, the chip 20 is disposed in such a manner that a circuit surface 20a of the chip 20 is opposed to a side of the third resin layer 3, and a back surface 20b of the chip 20 is opposed to a side of the fifth resin layer 5.

A thickness of the semiconductor chip 20 is substantially identical with that of the fourth resin layer 4. Accordingly, the semiconductor chip 20 can be passed through the fourth resin layer 4 in its thickness direction. In other words, the semiconductor chip 20 can be contained in a cavity or through hole 44a, illustrated in FIG. 2, in the fourth resin layer 4.

Further, as is illustrated, the multilayer circuit board 10 has, formed therein, interlayer wirings 12 and vias 13. The interlayer wirings 12 and vias 13 constitute electronic wirings, and are used to transfer signal information received at the electrode pad 21 of the chip 20.

In the multilayer circuit board 10, the interlayer wirings 12 are formed in an interface between the first resin layer 1 and the second resin layer 2, and in an interface between the second resin layer 2 and the third resin layer 3. In the illustrated embodiment, the interlayer wirings 12 each is an interlayer between two upper and lower resin layers, and is formed from a metal foil such as copper (Cu) foil by patterning the foil through etching, for example.

The vias 13 each is formed from an electrically conductive material in such manner that the via is passed through the resin layer in its thickness direction, and thus vias 13 are used to electrically connect the interlayer wirings 12 to each other, or electrically connect the interlayer wiring 12 to the electrode pad 21.

The vias 13 can be produced by hardening an electrically conductive paste such as metal paste filled in the via-forming through holes. In the illustrated embodiment, the vias 13 are formed in each of the second resin layer 2 and the third resin layer 3.

In this embodiment, the metal paste used in the formation of the vias 13 comprises mixed particles of two types of metals, i.e., silver (Ag) or copper (Cu) and tin (Sn), a solvent used for controlling a viscosity of the paste, and any conventional additives. When the metal paste is based on the metals Ag and Sn, the metals of the paste can be converted to the corresponding metal alloy Ag₃Sn upon sintering of the metals during pressing with heating.

In addition to the formation of the metal alloy, the metal Sn of the metal paste can form diffusion bonding with a copper (Cu) of the interlayer wiring 12 during pressing with heating. Further, since the electrode pad 21 of the semiconductor chip 20 has a nickel (Ni) plating applied on a surface thereof, the metal Sn of the metal paste can form diffusion bonding with the nickel of the electrode pad 21 during pressing with heating. The solvent in the metal paste will be evaporated during pressing with heating.

In the illustrated embodiment, the heat radiation member 30 such as a heat sink is laminated to a lower surface of the multilayer circuit board 10. In other words, the heat radiation member 30 is laminated in the circuit board 10 in a side of the back surface 20b of the semiconductor chip 20. As is illustrated, the heat radiation member 30 is laminated to the fifth resin layer 5. Further, in the illustrated embodiment, the heat radiation member 30 is an heat sink in the form of a plate, and is formed from a copper (Cu) because of its good thermal conductivity. A planar size of the heat radiation member 30 is substantially the same as that of the circuit board 10.

Referring to the fifth resin layer 5 positioned between the heat radiation member 30 and a back surface 20b of the semiconductor chip 20, the fifth resin layer 5 has a heat-releasing via 14 which was bored in the layer 5 in order to thermally connect the heat radiation member 30 to the semiconductor chip 20. The heat-releasing via 14 is a heat-conductive via hole formed passing through the fifth resin layer 5 in its thickness direction. Because of the presence of the heat-releasing via 14, heat generated in the chip 20 can be radiated through the via 14 from the heat radiation member 30.

The heat-releasing via 14 has a flat and rectangular configuration as in that of the semiconductor chip 20. Further, as is illustrated, an upper surface of the heat-releasing via 14 opposed to a bottom surface 20b of the semiconductor chip 20 has a surface area smaller than that of the bottom surface 20b of the chip 20, and an upper surface of the heat-releasing via 14 is full contact with the bottom surface 20b of the chip 20.

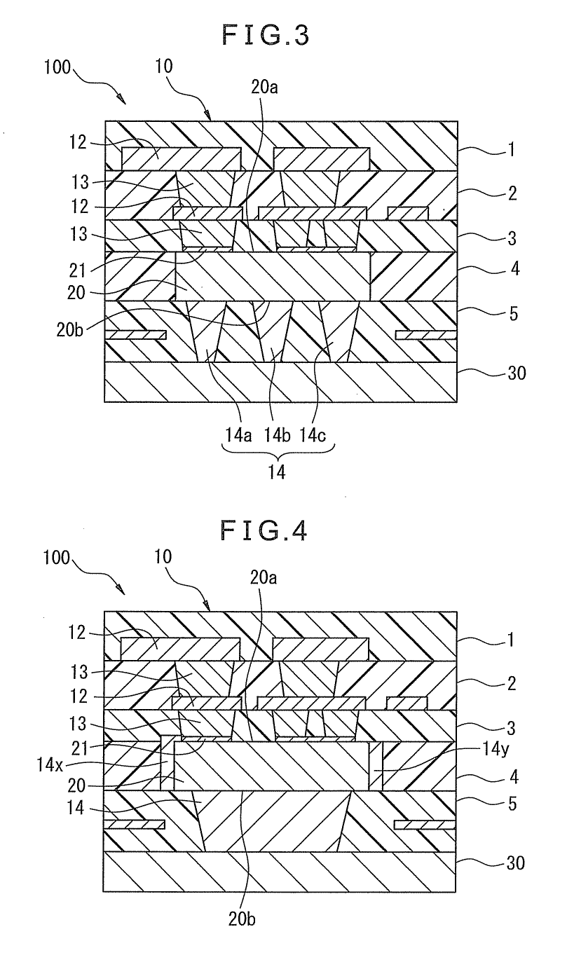

The heat-releasing via 14 has a flat and rectangular configuration. However, if desired, the via 14 may be formed in any other configurations. For example, the via 14 may a cylindrical rod as in the via 13 bored as a member of the electronic wiring described above, and as is illustrated in FIG. 3, in which three heat-releasing vias 14a, 14b and 14c in the form of a cylindrical rod are bored in the fifth resin layer 5 in place of the rectangular heat-releasing via 14 illustrated in FIG. 1. In this embodiment, two or more rod-shaped vias 14 may be formed in any desired patterns such as different numbers, and regular or random distributions.

As described above, the heat-releasing via 14 is preferred to be a hardened product of the metal paste. In this embodiment, the metal paste is constituted so that it comprise mixed metal particles such as Ag—Sn metal particles or Cu—Sn metal particles, a solvent used to control a viscosity of the paste, and any additives. Hereinafter, the metal paste used to form the heat-releasing via 14 will be described with reference to the metal of the formula: X—Sn in which X is Ag or Cu.

When used in the metal paste, the metal X—Sn forms a metal alloy X₃Sn as a result of the sintering during pressing with heat. Further, the Sn component of the metal paste forms a diffusion bond with the Cu component of the heat radiation member 30.

In addition, the metal paste forms an additional diffusion bond, since the semiconductor chip 20 has a plating layer such as nickel (Ni) or titanium (Ti) in its back surface 20b. In this embodiment, the Sn component of the metal paste forms a diffusion bond with the Ni or Ti component of the back surface 20b during pressing with heat. The solvent contained in the metal paste will be evaporated during pressing with heat.

In the present invention, the metal paste used is a ratio of the atomicity of Sn to the atomicity of X (Ag or Cu) and Sn, i.e., Sn/(X+Sn), and is 27 to 40%. In the metal paste, the atomicity of Sn and X (Ag or Cu) can be analyzed using the conventional apparatus such as energy dispersive X-ray analysis (EDX), electron probe microanalysis (EPMA), and X-ray photoelectron spectroscopy (ESCA).

Next, the production of the semiconductor device 100 will be described with reference to FIG. 2 which is a cross-sectional view of the semiconductor device 100 of FIG. 1 showing works used in the production of the illustrated device.

In the production of the semiconductor device 100, five resin films 41 to 45 each made of a thermoplastic resin are first prepared. These resin films are used to form the corresponding resin layers 1 to 5 (FIG. 1) in the subsequent step of pressing with heat. Hereinafter, the resin film 41 corresponding to the first resin layer 1 is called as the first resin film, and the resin film 42 corresponding to the second resin layer 2 is referred to as the second resin film. Similarly, the resin films 43 to 45 corresponding to the third to fifth resin layers 3 to 5 are called as the third to fifth resin films, respectively.

Next, when the resin film used is required to have a filled via, a required number of the via hole passed through the resin film is bored in the predetermined resin film in its thickness direction by using any desired fabrication means such as laser fabrication. The resulting via hole is then filled with a metal paste 46 using a screen printing method or other methods. In the illustrated embodiment, via holes were formed in each of the second resin film 42 and the third resin film 43, followed by filling the bored via holes with the metal paste 46. The metal paste 46 is used to form a via 13 (FIG. 1) in the subsequent step of pressing with heat. As described above, the metal paste 46 comprise metal particles such as Ag—Sn metal particles, a solvent used for controlling viscosity, etc.

Next, interlayer wirings 12 are formed in the predetermined resin film. In the illustrated embodiment, interlayer wirings 12 are formed in each of the first resin film 41 in its lower surface to be laminated to an upper surface of the second resin film 42, and the second resin film 42 in its lower surface to be laminated to an upper surface of the third resin film 43. In practice, the interlayer wirings 12 can be formed by applying a copper (Cu) foil to a lower surface of each of the resin films 41 and 42, followed by subjecting the copper foil to a pattern etching process to form a desired conductor pattern.

Further, a hole which is also referred herein to as a “through hole” or a “cavity” is formed in the predetermined resin layer by using any desired fabrication means such as laser fabrication. In the illustrated embodiment, a hole 44a passed through the film is formed in the fourth resin film 44 in its thickness direction. In view of errors in production, it is preferred that the hole 44a be formed in a rectangular configuration having a size which is slightly larger than the outer configuration of the semiconductor chip 20.

Furthermore, a via hole (not shown) passed through the film is formed in the fifth resin film 45 in its thickness direction by using any desired fabrication means such as laser fabrication, followed by filling the resulting via hole with a metal paste 48, as is illustrated in FIG. 2, by using, for example, screen printing.

As described above, the metal paste 48 comprise metal particles such as X (Ag or Cu)—Sn metal particles, a solvent used for controlling viscosity, etc. In the metal paste 48, a ratio of the atomicity of Sn to the atomicity of X (Ag or Cu) and Sn, i.e., Sn/(X+Sn), is in the range of 27 to 40%.

In the fifth resin film 45, the via hole has an upper surface in contact with the back surface 20b of the semiconductor chip 20 in the fourth resin film 44, and a surface area of the upper surface of the via hole is smaller than that of the back surface 20b of the semiconductor chip 20. Further, the upper surface of the via hole is fully laminated to and in contact with the back surface 20b of the semiconductor chip 20.

Thereafter, a lamination step is carried out. First, the heat radiation member 30, the fifth resin film 45 and the fourth resin film 44 are laminated in this order, after alignment of these film. Next, a semiconductor chip 20 is contained in a hole 44a of the fourth resin film 44 in the resulting laminate, followed by further laminating the third resin film 43, the second resin film 42 and the first resin film 41 to the chip-bearing laminate after alignment of the films 43 to 41. A laminate consisting of the first to fifth resin films 41 to 45 and the heat radiation member 30 is thus obtained.

Next, the laminate is subjected to a pressing step with heat in a pressing machine (not shown) to obtain a integrally pressed laminate of the resin films 41 to 45 and the heat radiation member 30 at once. For example, the pressing step can be carried out at a pressure of 5 MPa and a temperature of 320° C. for three hours.

Upon pressing with heat, the resin films 41 to 45 consisting of a thermoplastic resin are bonded to each other and at the same time, the fifth resin film 45 is bonded to the heat radiation member 30.

During pressing with heat, a thermoplastic resin of each of the third to fifth resin films 43 to 45 are fluidized and the fluidized resin is introduced and filled into a gap (clearance) created due to tolerance between the hole 44a of the fourth resin film 44 and the semiconductor chip 20, and thus the semiconductor chip 20 is sealed with the thermoplastic resin.

Further, during pressing with heat, the metal paste 46 is sintered to form a via 13 which further forms a diffusion bond with the interlayer wiring 12.

At the same time, during pressing with heat, the metal paste 48 is sintered to form a heat-releasing via 14 which further forms a diffusion bond with the semiconductor chip 20 and the heat radiation member 30.

After completion of the steps described above, a semiconductor device 100 shown in FIG. 1 is thus obtained. In the resulting semiconductor device 100, there is no phenomenon that the heat-releasing via 14 is undesirably routed into a side surface of the semiconductor chip 20. The diffusion bonding of the heat-releasing via 14 with each of the semiconductor chip 20 and the heat radiation member 30 is sufficiently attained in the semiconductor device 100.

The reasons why such desired results could be obtained in the semiconductor device 100 are as follows.

During pressing with heat, the metal X—Sn of the metal paste is subjected to a temperature of 150 to 200° C. to form a metal alloy X₃Sn. In this pressing step, the metal paste used contains a remainder of the Sn component which was not consumed in the formation of the alloy X₃Sn. According to the present invention, such a remainder of the Sn component can form a diffusion bond with the semiconductor chip 20 and the heat radiation member 30, when the metal paste is heated to a temperature of not less than 220° C.

Contrary to this, if the remainder of the Sn component in the used metal paste cannot form a diffusion bond with the chip 20 and the member 30, and thus an excess amount of the Sn component is still contained in the metal paste, the excess amount of the solid Sn component is converted to the corresponding liquid state. The liquid Sn component is then moved to and introduced into a gap formed between the semiconductor chip 20 and a hole 44a of the fourth resin film 44 due to a capillary action of gap. The Sn component is further moved to a circuit surface 20a of the semiconductor chip 20. As a result, the heat-releasing via 14 generates a short circuit problem since the Sn component of the via 14 is introduced into a side surface of the semiconductor chip 20.

The inventors have found through their studies that, as is described in the appended working examples, a ratio of the metal components X and Sn in the metal paste 48 is important to prevent an undesired introduction of the excess amount of the Sn component into a side surface of the semiconductor chip 20. Namely, when a ratio of the atomicity of the atom Sn to the atomicity of the atom (X+Sn) in which X=Ag or Cu, i.e., Sn/(X+Sn), is more than 40%, the excess amount of the Sn component is introduced into a side surface of the semiconductor chip 20.

Further, when a ratio of the atomicity Sn/(X+Sn) is less than 27%, a sufficient diffusion bond of the via 14 with the semiconductor chip 20 and heat radiation member 30 cannot be attained, since the amount of the Sn component in the metal paste is not sufficient to attain such a diffusion bond.

Contrary to this, according to the present invention, the above drawbacks can be avoided, since the metal paste 48 used for the formation of the heat-releasing via 14 has a ratio of the atomicity Sn/(X+Sn) of not more than 40%, no Sn component is introduced into a side surface of the semiconductor chip 20, and also no short circuit problem is caused due to the presence of the heat-releasing via 14.

Further, since the metal paste 48 has a ratio of the atomicity Sn/(X+Sn) of not less than 27%, a sufficient diffusion bond of the heat-releasing via 14 with the semiconductor chip 20 and heat radiation member 30 can be attained.

Furthermore, according to the present invention, the upper surface of the heat-releasing via 14 opposed to the semiconductor chip 20 has a surface area which is smaller than that of the bottom surface 20b of the semiconductor chip 20, and thus the upper surface of the heat-releasing via 14 is fully contacted with the bottom surface 20b of the semiconductor chip 20. Accordingly, the present invention is effective to avoid the drawbacks resulted in the prior art semiconductor devices in which the upper surface of the heat-releasing via 14 has a surface area which is larger than that of the bottom surface 20b of the semiconductor chip 20, i.e., drawbacks that upon pressing with heat, a composition constituting the metal paste 48 can be fluidized and fully introduced into a side surface of the semiconductor chip 20, thereby causing a short circuit due to the heat-releasing via 14.

As described above, according to the present invention, the drawbacks of the prior art semiconductor devices can be effectively removed because of the specific electrically conductive material in the heat-releasing via and the specific configuration of the heat-releasing via in the multilayer circuit board. For further understanding of these effects according to the present invention, the drawbacks of the prior art semiconductor devices will be described with reference to FIGS. 4 to 6.

The semiconductor device 100 illustrated in FIG. 4 corresponds to the semiconductor device 100 illustrated in FIG. 1 except that the heat-releasing via 14 was formed from the conventional Pb-free solder, i.e., eutectic solder such as Sn—Pb or Sn—Ag—Cu. Upon pressing the laminated structure with application of heat in the production of the semiconductor device 100, a composition constituting the metal paste 48 is changed to the corresponding liquid state, and an excess amount of the Sn component in the liquid state is fluidized and introduced into a side surface and circuit surface 20a of the semiconductor chip 20. Accordingly, as is illustrated in FIG. 4, the resulting semiconductor device 100 includes undesired fluidized and hardened metal portions 14x and 14y around the semiconductor chip 20 which can cause a short circuit, accordingly, in addition to the via 14.

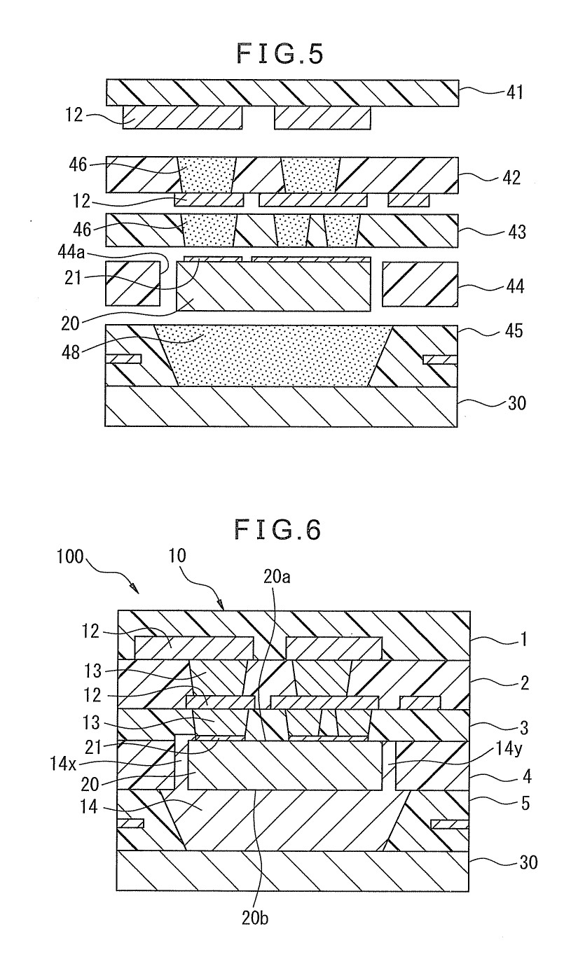

The semiconductor device 100 illustrated in FIGS. 5 and 6 corresponds to the semiconductor device 100 illustrated in FIGS. 2 and 1, respectively, except that as is illustrated, an upper surface of the heat-releasing via 14 has a surface area larger than that of the bottom surface 20b of the semiconductor chip 20. In both the semiconductor devices 100, the heat-releasing via 14 was formed from the metal paste containing mixed metal particles of Ag or Cu and Sn.

Upon pressing the laminated structure with application of heat in the production of the semiconductor device 100, a composition constituting the metal paste 48 is changed to the corresponding liquid state, and the liquid metal paste is introduced into a side surface and circuit surface 20a of the semiconductor chip 20. Accordingly, as is illustrated in FIG. 6, the resulting semiconductor device 100 includes undesired fluidized and hardened portions 14x and 14y around the semiconductor chip 20 which can cause a short circuit, accordingly, in addition to the via 14.

The preferred embodiments of the present invention were described above. However, the present invention should not be restricted to these embodiments. The present invention may be widely modified and improved within the scope and spirit of the present invention. For example, a number of the resin layers constituting the multilayer circuit board 10 may be freely increased or reduced depending upon the desired effects and other factors.

Further, the resin layers constituting the multilayer circuit board 10 may be freely changed. For example, the chip-incorporated resin layer may be changed in the multilayer circuit board 10. Referring to the illustrated embodiments, a semiconductor chip 20 was contained in a hole 44a of the fourth resin layer 44. However, the semiconductor chip 20 may be contained in other resin layers, or two or more semiconductor chips 20 may be contained in two or more holes in the fourth resin layer 44 and/or other resin layers. In such instances, it is preferred that heat-releasing vias 14 are formed in all the resin layers disposed between the semiconductor chip 20 and the heat radiation member 30 in order to ensure a heat-releasing route consisting of a conductor metal between the semiconductor chip 20 and the heat radiation member 30.

In the illustrated embodiments, an upper surface of the heat-releasing via 14 opposed to a bottom surface 20b of the semiconductor chip 20 had a surface area smaller than that of the bottom surface 20b of the semiconductor chip 20. However, if desired, the upper surface of the via 14 may have a surface area which is substantially identical with that of the bottom surface 20b of the chip 20. The inventors have found that such an embodiment is sufficient to prevent undesirable introduction of the fluidized Sn component into a side surface of the semiconductor chip 20 and also generation of a short circuit problem.

### EXAMPLES

The present invention will be further described with reference to the examples thereof.

### Examples 1 to 5 and Comparative Examples 1 to 4

In these examples, nine (9) type of metal pastes described in the following Table 1 were prepared to form the heat-releasing via 14. As is described in Table 1, the metal pastes each had a different ratio (%) of atomicity with regard to Ag and Sn in the metal particles. The metal paste was prepared by kneading the Ag and Sn metal particles with terpineol as an organic solvent.

Next, using the prepared metal paste, the semiconductor device 100 described above referring to FIG. 1 was produced in accordance with the production process described above referring to FIG. 2.

In the semiconductor device 100, the heat radiation member 30 was a heat sink made of copper (Cu). The semiconductor chip 20 was a silicon chip, and had an electrode pad 21, made of aluminum (Al), fabricated on an upper surface 20a thereof, and a nickel (Ni) plating deposited on a back surface 20b thereof. The resin films 41 to 45 each was a film made of a polyetheretherketone resin and a polyeterimide resin.

After a laminate of the resin films 41 to 45 was combined with the heat radiation member 30 as is illustrated in FIG. 2, the combined article was subjected to a pressing step under the application of heat. The pressing step was conducted with the pressure of 5 MPa at the temperature of 320° C. for three hours. The semiconductor device 100 illustrated in FIG. 1 was thus obtained.

### Test 1

The semiconductor device 100 obtained was tested with respect to the operating characteristics of the semiconductor chip 20 fabricated therein. In the test of the operation characteristics, defects produced in the semiconductor chip 20 were inspected. The semiconductor device 100 having no defect was evaluated as “good”. When defective bonding of the heat-releasing via 14 and a short circuit between an electrode pad 21 on a surface 20a and a back surface 20b of the semiconductor chip 20 was observed, the semiconductor device 100 was evaluated as “bad”. The results of inspection are summarized in the following Table 1.

TABLE 1

| | | Comparative | | | | | | | Comparative | |
|---|---|---|---|---|---|---|---|---|---|---|
| | | example | | Example | | | | | example | |
| | | 1 | 2 | 1 | 2 | 3 | 4 | 5 | 3 | 4 |
| A | Ag | 80 | 75 | 73 | 70 | 65 | 63 | 60 | 57 | 55 |
| | Sn | 20 | 25 | 27 | 30 | 35 | 37 | 40 | 43 | 45 |

| | | | | | | | | | |
|---|---|---|---|---|---|---|---|---|---|
| B | bad | bad | good | good | good | good | good | bad | bad |

A: ratio of atomicity (%)
B: results of inspection

As will be appreciated from Examples 1 to 5 in Table 1, the operating characteristics of the semiconductor chip 20 were normal and acceptable, when a ratio of the atomicity Sn/(Ag+Sn) is in the range of 27 to 40%. Namely, the connection between the heat-releasing via 14 and the heat radiation member 30 and the connection between the heat-releasing via 14 and a back surface 20b of the semiconductor chip 20 were good, and no short circuit due to the heat-releasing via was generated.

In these examples, when the metal paste used in Example 3 was sintered, the XRD (X-ray diffraction) analysis showed that the metal of the metal paste was converted to a metal alloy Ag₃Sn. Further, in the semiconductor device 100 produced in Example 3, the electron microscopic inspection and the XRD analysis showed that a Sn diffusion layer (Cu₃Sn) was formed on a surface of the heat radiation member 30 opposed to the heat-releasing via 14.

Accordingly, it will be appreciated from the above results that during pressing with heat, particles of the Ag metal and particles of the Sn metal are sintered to form a metal alloy Ag₃Sn, and an excess amount of Sn not used in the formation of the Ag₃Sn alloy is used to form the connection between the heat-releasing via 14 and the heat radiation member 30 and the connection between the heat-releasing via 14 and a back surface 20b of the semiconductor chip 20.

Further, as will be appreciated from Comparative Examples 1 and 2 in Table 1, when the atomicity ratio of Sn is 20% or 25%, irregularity of the operating characteristics was observed as defects in the semiconductor chip 20. Further, it was observed that the connection between the heat-releasing via 14 and the heat radiation member 30 and the connection between the heat-releasing via 14 and a back surface 20b of the semiconductor chip 20 were not good.

In order to confirm why the above drawbacks were caused, the cross-section of the semiconductor device 100 produced in Comparative Example 2 was observed on the electron microscope. The results showed that no Sn diffusion layer was formed on a surface of the heat radiation member 30 opposed to the heat-releasing via 14. Similarly, no Sn diffusion layer was formed in a back surface 20b of the semiconductor chip 20. This is because, as is appreciated from the state diagram (not shown) of the Ag—Sn binary alloy, Ag₃Sn is stably formed in the composition area of the Ag—Sn binary alloy in which Ag₃Sn can be produced, and thus, when the atomicity ratio of Sn is not more than 25%, all Sn can be consumed to form Ag₃Sn and therefore no excess Sn is resulted in the metal paste.

In this connection, it is appreciated that, when the atomicity ratio of Sn is 26%, i.e., when an amount of excess Sn is smaller than when the atomicity ratio of Sn is 27%, insufficient connection between the heat-releasing via 14 and the heat radiation member 30 and insufficient connection between the heat-releasing via 14 and a back surface 20b of the semiconductor chip 20 will be resulted.

Further, as will be appreciated from Comparative Examples 3 and 4 in Table 1, when the atomicity ratio of Sn is 43% or 45%, irregularity of the operating characteristics was observed as defects in the semiconductor chip 20, along with a short circuit due to the heat-releasing via 14.

In order to confirm the why the above drawbacks were caused, the cross-section of the semiconductor device 100 produced in Comparative Example 3 was observed on the optical microscope and the electron microscope. The results showed that a metal layer was deposited on a side surface of the semiconductor chip 20. The EDX analysis showed that the metal layer is made of tin (Sn).

Further, the observation on the electron microscope and the XRD analysis of the semiconductor device 100 showed that a Sn diffusion layer (Cu₃Sn) was formed on a surface of the heat radiation member 30 opposed to the heat-releasing via 14. Furthermore, the XRD analysis showed that the heat-releasing via 14 was substantially formed from Ag₃Sn alloy.

Accordingly, it is appreciated from the above results that during pressing with heat, particles of the Ag metal and particles of the Sn metal are sintered to form a metal alloy Ag₃Sn, and an excess amount of Sn not used in the formation of the Ag₃Sn alloy is used to form the connection between the heat-releasing via 14 and the heat radiation member 30, and an excess amount of Sn not used in the formation of this connection is eluted or fluidized and thus introduced into a side surface of the semiconductor chip 20.

In addition, it will be appreciated from Examples 1 to 5 that the adjustment of the atomicity ratio of Sn to that of all of Ag and Sn to not more than 45% which is intended to prevent introduction of an eluted Sn in an excess amount to a side surface of the semiconductor chip 20 is effective for a metal paste 48 used in the formation of the heat-releasing via 14 to be bonded to the heat radiation member 30, and is not effective for a metal paste 46 used in the formation of the via 13 to be bonded to the interlayer wiring 12. This is because the heat radiation member 30 generally has a thickness of not less than 500 μm which is thicker than the thickness of the interlayer wiring 12, and thus different amounts of the Sn component are used in the formation of the diffusion bonds with the heat radiation member 30 and the heat-releasing via 14 and in the formation of the diffusion bonds with the interlayer wiring 12 and the via 13.

### Test 2

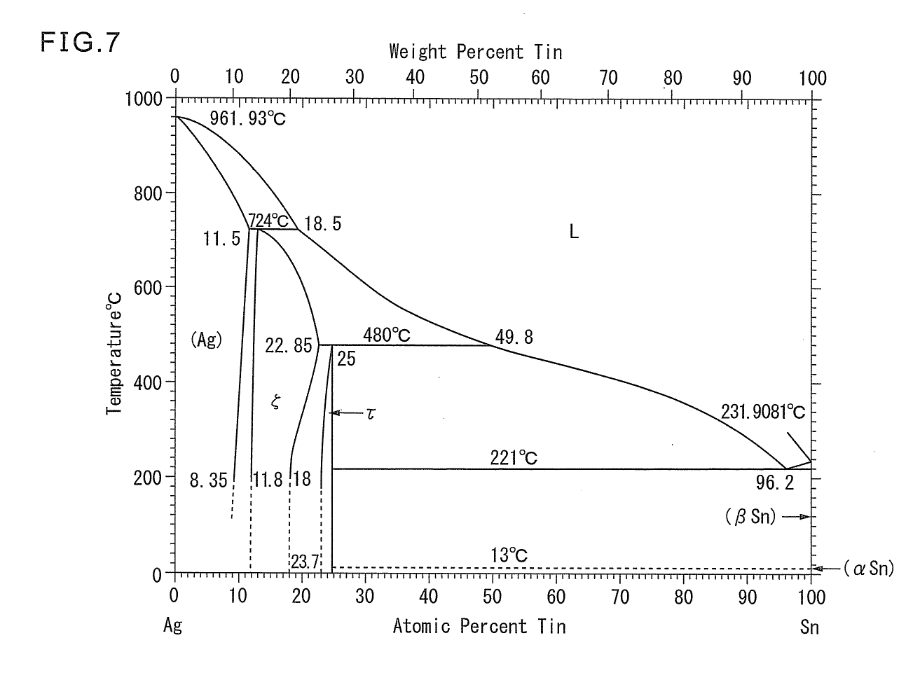

The semiconductor device 100 obtained was tested with respect to the formation of defects in the semiconductor chip 20. In this test, The semiconductor device 100 having no defect was evaluated as “good”. When the formation of defects was observed, the semiconductor device 100 was evaluated as “bad”. The results of test are summarized in the following Table 2, along with the state diagram of the Ag—Sn binary alloy shown in FIG. 7.

TABLE 2

| | | Comparative | | | | | | | Comparative | |
|---|---|---|---|---|---|---|---|---|---|---|
| | | example | | Example | | | | | example | |
| | | 1 | 2 | 1 | 2 | 3 | 4 | 5 | 3 | 4 |
| A | Ag | 80 | 75 | 73 | 70 | 65 | 63 | 60 | 57 | 55 |
| | Sn | 20 | 25 | 27 | 30 | 35 | 37 | 40 | 43 | 45 |

| | | | | | | | | | |
|---|---|---|---|---|---|---|---|---|---|
| B | bad | bad | good | good | good | good | good | bad | bad |

A: ratio of atomicity (%)
B: formation of defects

It will be appreciated from the results of Table 2 and the state diagram of the Ag—Sn binary alloy of FIG. 7 that the Ag—Sn binary alloy described in Examples 1 to 5 are preferably used in order to conduct the pressing of the laminated body with heat at a temperature of not lower than 300° C., since an excess amount of Sn not consumed in the bonding of Ag₃Sn could be used to form a connection with a Cu electrode pad and a Ni plating on a surface of the Si chip. Ag₃Sn was formed when the atomicity ratio of Sn to that of all of Ag and Sn is 25%.

Contrary to this, in Comparative Examples 1 and 2 in which the atomicity ratio of Sn is smaller than 27%, all Sn contained is consumed to form a bond with Ag, thereby forming Ag₃Sn. Accordingly, no diffusion bond of Cu—Sn (Cu₃Sn) is formed, and thus no connection with the Cu electrode and with the Ni plating on a surface of the Si chip is formed in these comparative examples.

Further, in Comparative Examples 3 and 4, since the metal paste contains an excess amount of Sn, Sn was not completely consumed in the formation of Ag₃Sn and Cu—Sn, and the bond with the Ni plating. A remainder of Sn was thus eluted and fluidized during pressing with heat, thereby causing a short circuit problem. Further, there was a tendency that the excess amount of Sn results in a reduction of the strength of the device.

### Examples 6 to 10 and Comparative Examples 5 to 8

The procedure described in Examples 1 to 5 described above was repeated in these examples. However, in these examples, metal pastes containing particles of Cu and Sn were prepared in accordance with the manner described in Examples 1 to 5 in order to produce a heat-releasing via made of a Cu—Sn binary alloy in place of the Ag—Sn binary alloy. Accordingly, as is appreciated from the following Table 3, Examples 6 to 10 and Comparative Examples 5 to 8 correspond to Examples 1 to 5 and Comparative Examples 1 to 4, respectively.

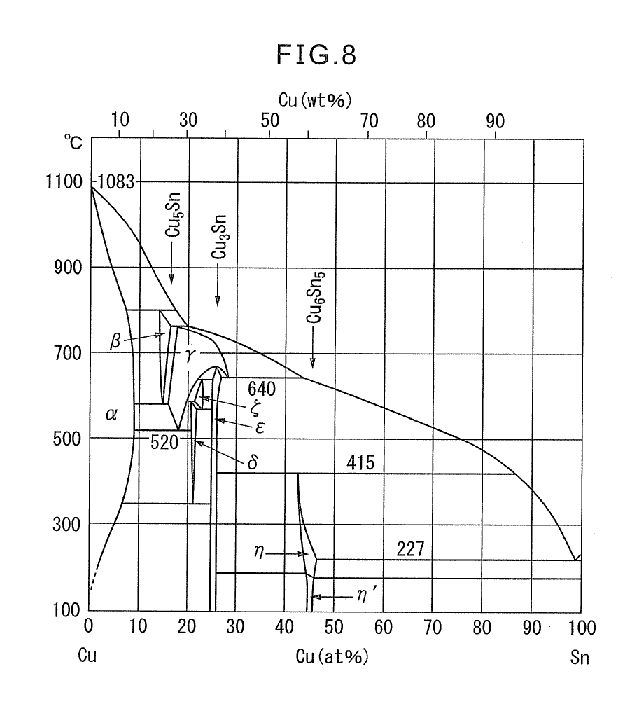

After the semiconductor device 100 was produced in accordance with the manner described in Examples 1 to 5, the device 100 was tested with respect to the formation of defects in the semiconductor chip 20. In this test, the semiconductor device 100 having no defect was evaluated as “good”. When the formation of defects was observed, the semiconductor device 100 was evaluated as “bad”. The results of test are summarized in the following Table 3, along with the state diagram of the Cu—Sn binary alloy shown in FIG. 8.

TABLE 3

| | | Comparative | | | | | | | Comparative | |
|---|---|---|---|---|---|---|---|---|---|---|
| | | example | | Example | | | | | example | |
| | | 5 | 6 | 6 | 7 | 8 | 9 | 10 | 7 | 8 |
| A | Cu | 80 | 75 | 73 | 70 | 65 | 63 | 60 | 57 | 55 |
| | Sn | 20 | 25 | 27 | 30 | 35 | 37 | 40 | 43 | 45 |

| | | | | | | | | | |
|---|---|---|---|---|---|---|---|---|---|
| B | bad | bad | good | good | good | good | good | bad | bad |

A: ratio of atomicity (%)
B: formation of defects

It will be appreciated from the results of Table 3 and the state diagram of the Cu—Sn binary alloy of FIG. 8 that the Cu—Sn binary alloy described in Examples 6 to 10 are preferably used in order to conduct the pressing of the laminated body with heat at a temperature of not lower than 300° C., since an excess amount of Sn not consumed in the bonding of Cu₃Sn could be used to form a connection with a Cu electrode pad and a Ni plating on a surface of the Si chip. Cu₃Sn is formed when the atomicity ratio of Sn to that of all of Sn and Cu is 25%.

Contrary to this, in Comparative Examples 5 and 6 in which the atomicity ratio of Sn is smaller than 27%, all Sn contained is consumed to form a bond with Cu, thereby forming Cu₃Sn. Accordingly, no diffusion bond of Cu—Sn (Cu₃Sn) is formed, and thus no connection with the Cu electrode and with the Ni plating on a surface of the Si chip is formed in these comparative examples.

Further, in Comparative Examples 7 and 8, since the metal paste contains an excess amount of Sn, Sn was not completely consumed in the formation of Cu₃Sn and Cu—Sn, and the bond with the Ni plating. A remainder of Sn was thus eluted and fluidized during pressing with heat, thereby causing a short circuit problem. Further, there was a tendency that the excess amount of Sn results in a reduction of the strength of the device.

### Example 11

The procedure described in Examples 1 to 5 described above was repeated in this example. However, in this example, a metal paste having an atomicity ratio (%) of Sn to Cu and Sn of 30% was prepared to produce the semiconductor device 100 shown in FIG. 1. The tests showed that the operating characteristics of the semiconductor chip 20 were normal and acceptable.

In this example, when the metal paste used was sintered, the XRD analysis showed that the sintered product was substantially formed from Cu₃Sn alloy. Further, the electron microscopic inspection and the XRD analysis showed that a Sn diffusion layer (Cu₃Sn) was formed on a surface of the heat radiation member 30 opposed to the heat-releasing via 14.

Further, as is appreciated from the state diagram (not shown) of the Cu—Sn binary alloy, when Cu and Sn are reacted in the Cu—Sn binary alloy, if an atomicity ratio (%) of Sn to Cu and Sn is in the range of 20 to 45%, Cu₃Sn is substantially formed stably. In this connection, it should be noted that an atomicity ratio (%) of Sn to Ag or Cu and Sn is substantially identical in both of the atomicity ratio of Ag₃Sn and the atomicity ratio of Cu₃Sn.

Therefore, when a metal paste containing particles of Cu—Sn metal is used in place of the metal paste containing particles of Ag—Sn metal used in Examples 1 to 5 described above, if an atomicity ratio (%) of Sn to Cu and Sn is in the range of 20 to 45%, an atomicity ratio (%) of Sn consumed during the sintering of the metal particles is identical with that observed in Examples 1 to 5 and Comparative Examples 1 to 4.

Accordingly, when a metal paste containing particles of Cu—Sn metal is used in place of the metal paste containing particles of Ag—Sn metal, if an atomicity ratio (%) of Sn to Cu and Sn is in the range of 27 to 40% as in Examples 1 to 5, it becomes possible to obtain a good connection between the heat-releasing via 14 and the heat radiation member 30 and a good connection between the heat-releasing via 14 and a back surface 20b of the semiconductor chip 20, along with prevention of the short circuit due to the heat-releasing via.

1. An electrically conductive material used in the formation of heat-releasing filled via holes in an electronic component-incorporated multilayer circuit board with a heat radiation member, in which
the electrically conductive material comprises metal particles as a conductive metal which is a mixture of a first conductive metal consisting of silver (Ag) or copper (Cu) and a second conductive metal consisting of tin (Sn), and a ratio of the atomicity of tin to the atomicity of silver or copper and tin is 27 to 40%.

2. The electrically conductive material according to claim 1, in which the electrically conductive material is an electrically conductive paste comprising the metal particles in an organic binder.

3. The electrically conductive material according to claim 1 or 2, in which the multilayer circuit board comprises two or more laminated conductive resin layers and at least one conductive resin interlayer having at least one cavity in which one or more electronic components are built-in, the interlayer being sandwiched between the adjacent resin layers,
the heat radiation member is laminated to one or both surfaces of the multilayer circuit board, and
one or more heat-releasing filled via holes are formed in at least one of the laminated conductive resin layers, and the electronic components and the heat radiation member are thermally connected to each other via the filled via holes to radiate heat, generated in the electronic components, from the heat radiation member.

4. The electrically conductive material according to claim 3, in which the heat-releasing filled via holes have a heat-receiving surface which is in contact with a heat-releasing surface of the electronic components, and the heat-receiving surface of the filled via holes has a surface area which is smaller than that of the heat-releasing surface of the electronic components.

5. The electrically conductive material according to claim 1 or 2, in which the electronic component is a semiconductor chip.

6. An electronic device comprising an electronic component-incorporated multilayer circuit board with heat-releasing filled via holes, and a heat radiation member, in which
the multilayer circuit board comprises two or more laminated conductive resin layers and at least one conductive resin interlayer having at least one cavity in which one or more electronic components are built-in, the interlayer being sandwiched between the adjacent resin layers,
the heat radiation member is laminated to one or both surfaces of the multilayer circuit board,
one or more heat-releasing filled via holes are formed in the laminated conductive resin layers, and the electronic components and the heat radiation member are thermally connected to each other to radiate heat, generated in the electronic components, from the heat radiation member, and
the heat-releasing filled via holes comprises, filled therein, a sintered product of an electrically conductive material comprising metal particles as a conductive metal which is a mixture of a first conductive metal consisting of silver (Ag) or copper (Cu) and a second conductive metal consisting of tin (Sn), and a ratio of the atomicity of tin to the atomicity of silver or copper and tin is in the range of 27 to 40%.

7. The electronic device according to claim 6, in which the heat-releasing filled via holes have a heat-receiving surface which is in contact with a heat-releasing surface of the electronic components, and the heat-receiving surface of the filled via holes has a surface area which is smaller than that of the heat-releasing surface of the electronic components.

8. The electronic device according to claim 6 or 7, in which the electrically conductive material is an electrically conductive paste comprising the metal particles in an organic binder.

9. The electronic device according to claim 6 or 7, in which the electronic component is a semiconductor chip.

10. The electronic device according to claim 6 or 7, in which the heat radiation member is a heat sink.

11. The electronic device according to claim 6 or 7, in which the electronic device is used in automotive parts.
